(19) United States
(12) Patent Application Publication
(10) Pub. No.: US 2014/0139980 A1
(43) Pub. Date: May 22, 2014

(54) ELECTRONIC APPARATUS

(71) Applicant: Kabushiki Kaisha Toshiba, Tokyo (JP)

(72) Inventors: Yasuyuki HORII, Ome-shi (JP); Yasuyuki SUZUKI, Tachikawa-shi (JP)

(73) Assignee: Kabushiki Kaisha Toshiba, Tokyo (JP)

(21) Appl. No.: 13/974,990

(22) Filed: Aug. 23, 2013

Related U.S. Application Data
(63) Continuation of application No. PCT/JP2013/057936, filed on Mar. 13, 2013.

(30) Foreign Application Priority Data
Nov. 21, 2012 (JP) 2012-255533

(51) Int. Cl. H05K 5/03

(52) U.S. Cl. CPC H05K 5/03
USPC 361/679.01

(57) ABSTRACT

According to one embodiment, an electronic apparatus comprises a main body and a pivotable member. The pivotable member comprises an end which enters between the rear end of the main body and an installation surface. A protector is provided at the end of the pivotable member. The protector includes a base part fixed inside the end of the pivotable member, and a protrusion protruding outside of the end from the base part. The protrusion is configured to make contact with the installation surface when the pivotable member lies back behind the main body, and the base part has a greater shape than the protrusion.

### CROSS REFERENCE TO RELATED APPLICATIONS

This application is a Continuation Application of PCT Application No. PCT/JP2013/057936, filed Mar. 13, 2013 and based upon and claiming the benefit of priority from Japanese Patent Application No. 2012-255533, filed Nov. 21, 2012, the entire contents of all of which are incorporated herein by reference.

### FIELD

Embodiments described herein relate generally to an electronic apparatus.

### BACKGROUND

The portable computer which is an example of electronic apparatus comprises a main body set on, for example, a top plate of a desk, and a display supported to be pivotable on a back end of the main body. In a portable computer of a type in which a base end of a display enters between a top plate and a rear end of a main body when the display is pivoted to lie down behind the main body, a protector is provided on an outer circumferential surface of the base end of the display.

The protector is an element for preventing the base end of the display or the top plate from being abraded and damaging each other. The protector is configured by, for example, a rubber elastic material such as elastomer. According to a conventional portable computer, the protector is bonded to the outer circumferential surface of the base end of the display by an adhesive bond or double-sided adhesive tape. Therefore, for example, when an impact is applied to the protector, the protector may be separate or drop from the base end of the display.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of a portable computer according to the first embodiment;

FIG. 2 is an exemplary side view of the portable computer, showing a state of the display pivoted to an exploded position where the display lies down behind the main body;

FIG. 3 is an exemplary enlarged side view of a portion denoted at F3 in FIG. 2;

FIG. 4 is an exemplary perspective view of the portable computer, showing a shape of a protector provided on the display;

FIG. 5 is an exemplary sectional view showing a configuration of the portable computer on the display;

FIG. 6 is an exemplary sectional view of the portable computer, showing a state of the protector in contact with a mount surface;

FIG. 7 is an exemplary front view of the display;

FIG. 8 is an exemplary sectional view along a line F8-F8 in FIG. 7;

FIG. 9 is an exemplary perspective view of a display cover which forms a par of a second housing;

FIG. 10 is an exemplary enlarged perspective view of a portion denoted at F10 in FIG. 9;

FIG. 11 is an exemplary enlarged perspective view of a portion denoted at F11 in FIG. 9;

FIG. 12A is an exemplary front view of the protector;

FIG. 12B is an exemplary side view of the protector;

FIG. 12C is an exemplary perspective view of the protector;

FIG. 13 is an exemplary perspective view of a portable computer, showing a shape of a protector provided on a display, according to the second embodiment; and

FIG. 14 is an exemplary perspective view of a portable computer, showing a shape of a protector provided on a display, according to the third embodiment.

### DETAILED DESCRIPTION

Various embodiments will be described hereinafter with reference to the accompanying drawings. In general, according to one embodiment, an electronic apparatus comprises a main body placed on an installation surface, and a pivotable member pivotably supported at a rear end of the main body. The pivotable member comprises an end which enters between the rear end of the main body and the installation surface, when the pivotable member is pivoted to a position where the pivotable member lies down behind the body. A protector is provided at an end of the pivotable member. The protector comprises a base part fixed inside the end of the pivotable member, and a protrusion protruding outside of the end from the base part. The protrusion is configured to make contact with the installation surface when the pivotable member lies down behind the body, and the base part has a greater shape than the protrusion.

### First Embodiment

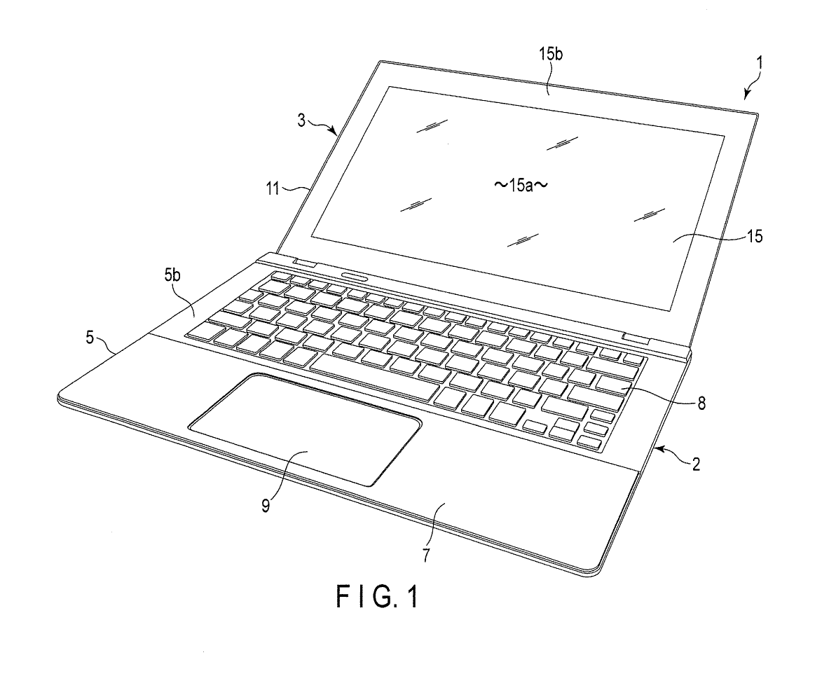

Hereinafter, the first embodiment of the will be described with reference to FIGS. 1 to 12.

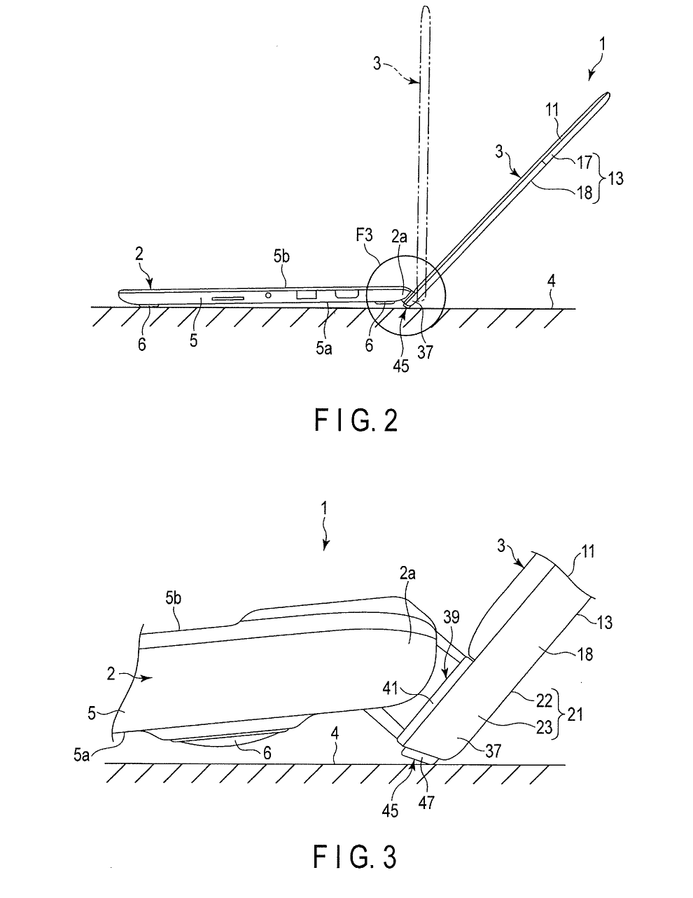

FIG. 1 and FIG. 2 disclose a portable computer 1 which is an example of an electronic apparatus. The portable computer 1 comprises a main body 2 and a display 3. The main body 2 is an element placed, for example, a horizontal installation surface 4 such as a top plate of a desk. The main body 2 comprises a first housing 5. The first housing 5 contains main components, such as a mother board with a CPU mounted thereon, and a hard disk drive.

The first housing 5 comprises a bottom surface 5a and an upper surface 5b. A plurality of feet 6 are provided on the bottom surface 5a of the first housing 5. The feet 6 protrude from four corner parts of the bottom surface 5a, and are brought into contact with the installation surface 4. The feet 6 are made of a rubber-based elastic material such as elastomer, to prevent the main body 2 sliding in relation to the installation surface 4.

A palm rest 7 and a keyboard 8 are provided on the upper surface 5b of the first housing 5. The palm rest 7 is extended in a width direction of the first housing 5 in a front half of the upper surface 5b. A touchpad 9 is arranged in a center part of the palm rest 7. The keyboard 8 is exposed to the upper surface 5b of the first housing 5 in the back of the palm rest 7.

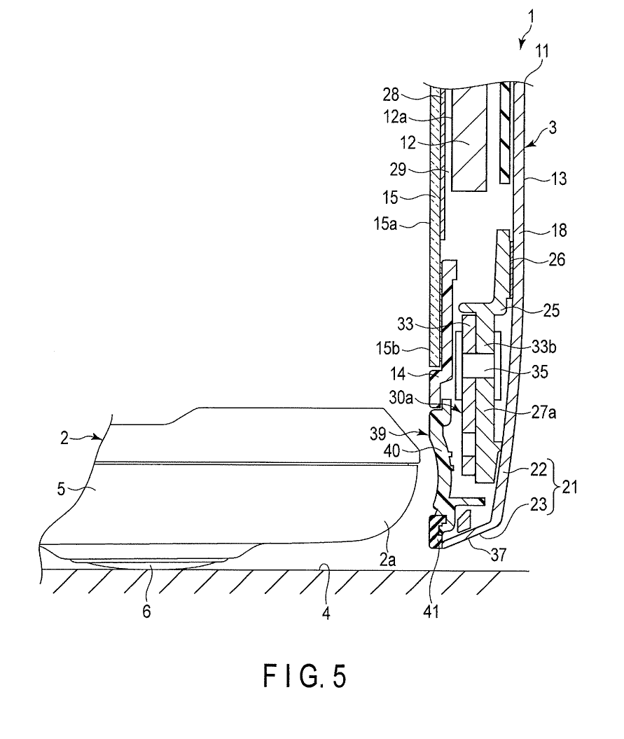

The display 3 is an example of a pivotable member. The display 3 comprises the second housing 11 and a display module 12, as shown in FIGS. 5, 6, and 7. The second housing 11 is configured by, for example, a display cover 13, a display mask 14, and a front panel 15, for example.

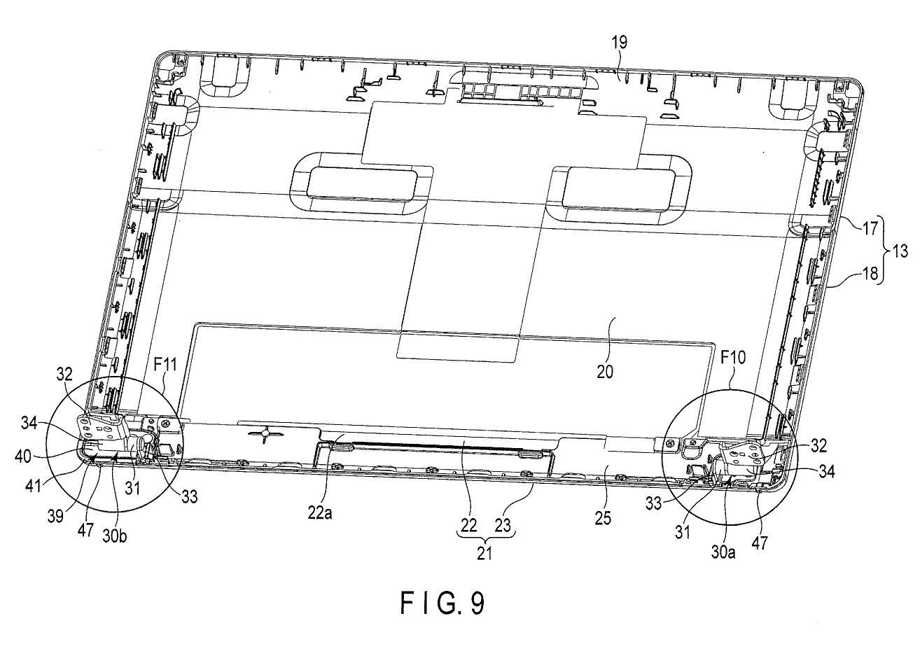

As shown in FIGS. 2 and 9, the display cover 13 in the first embodiment is configured by combining the first cover part 17 and the second cover part 18 with each other. The first cover part 17 is made of a synthetic resin material. The second cover part 18 is made of, for example, a metal material such as aluminum.

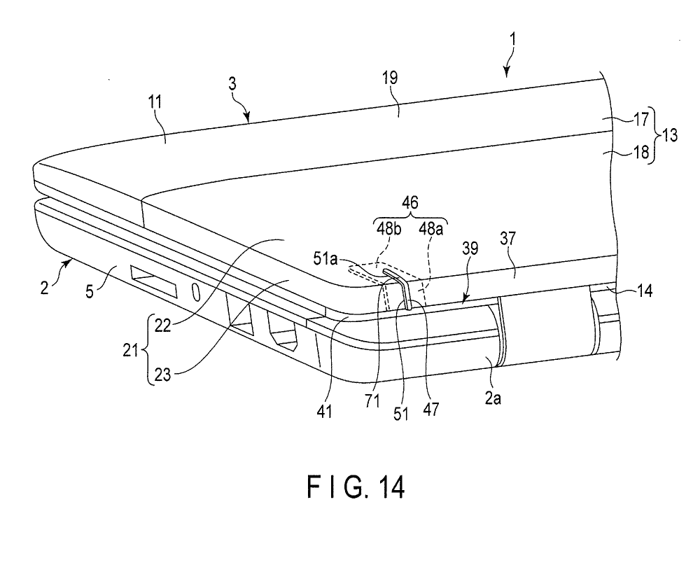

The first cover part 17 comprises a shell part 19 exposed outside from the second housing 11, and an inner wall part 20 which continues to the shell part 19. The second cover part 18 covers over an outer surface of the inner wall part 20 of the first cover part 17 and is fixed to the inner wall part 20, for example, by bonding. Therefore, as most appropriately shown in FIG. 14, the second cover part 18 comprises an outer wall 21 exposed to outside of the second housing 11. The outer wall 21 continues to the shell part 19 of the first cover part 17.

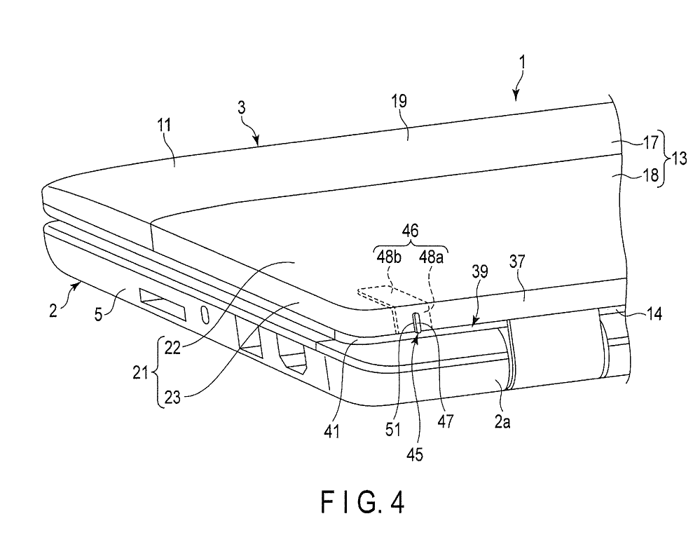

As shown in FIGS. 4 to 11, the outer wall 21 comprises a main wall part 22 and a peripheral wall part 23 which extends from peripheral edges of the main wall part 22. Most of the inner surface area of the main wall part 22 is covered by the inner wall part 20 of the first cover part 17. In other words, the inner surface of the main wall part 22 includes an area 22a which is out of the inner wall part 20. In an end along the height direction of the second housing 11, the area 22a has an elongate shape extending in the width direction of the second housing 11.

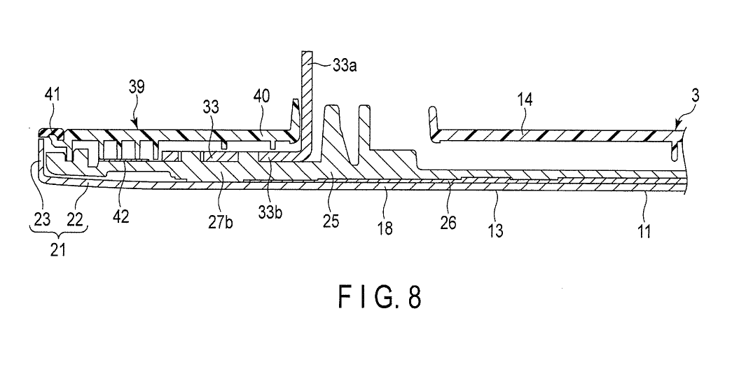

As shown in FIG. 8 and FIG. 9, a middle frame 25 is arranged on the area 22a of the main wall part 22. The middle frame 25 is an example of a holder member. The middle frame 25 is made of, for example, a metal material such as magnesium alloy. The middle frame 25 has an elongate shape extending in the width direction of the second housing 11. The middle frame 25 is fixed to the area 22a of the main wall part 22 with an adhesive agent 26, and is surrounded by the peripheral wall part 23 of the second cover part 18.

The middle frame 25 has a pair of hinge fixing parts 27a and 27b. The hinge fixing parts 27a and 27b are formed in a flat plate shape. The hinge fixing parts 27a and 27b are distant from each other in the width direction of the second housing 11.

The display mask 14 is made of a synthetic resin material. The display mask 14 has an elongate shape extending in the width direction of the second housing 11. The display mask 14 is engaged in the peripheral wall part 23 of the second cover part 18, at an end along the height direction of the second housing 11. According to the first embodiment, the display mask 14 covers a center part of the middle frame 25 which connects the hinge fixing parts 27a and 27b.

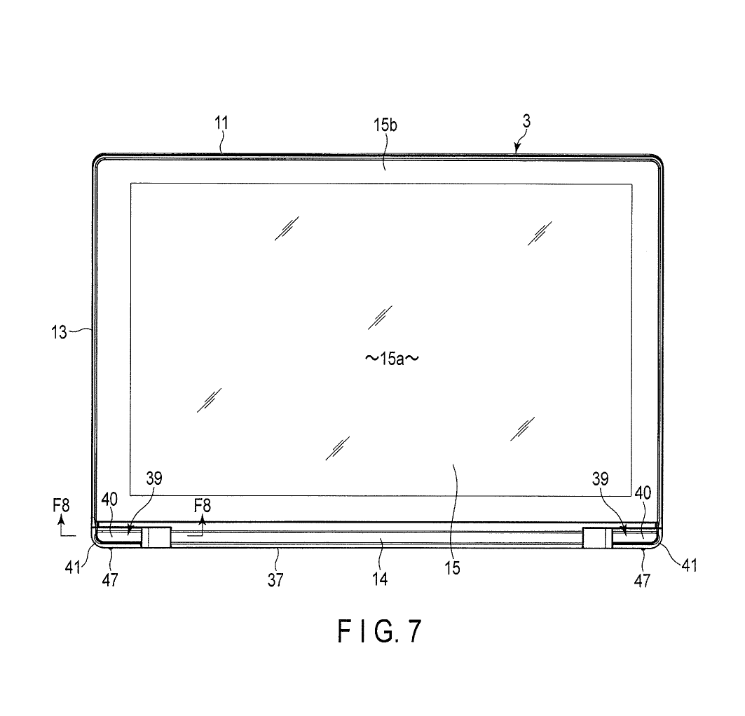

The front panel 15 is made of, for example, a light-transmissible material such as glass or plastic. As shown in FIGS. 1 and 7, the front panel 15 comprises a rectangular transparent display area 15a, and an opaque mask part 15b which surrounds the display area 15a. The display area 15a and the mask part 15b are positioned on the same surface. Further, a touch sensor 28 of a piezoelectric or electrostatic type which further has a hand-writing input function is bonded to the back surface of the display area 15a of the front panel 15.

The front panel 15 is engaged in the display cover 13, and an edge of the front panel 15 is layered over the display mask 14. Therefore, the front panel 15 cooperates with the display mask 14 to cover an open end of the display cover 13.

As shown in FIG. 5, the display module 12 intervenes between the display cover 13 and the front panel 15. The display module 12 comprises a rectangular display screen 12a which displays images and videos. The display screen 12a faces the back surface of the touch sensor 28. Between the display screen 12a and the touch sensor 28, a gap 29 is maintained to prevent a moire pattern.

The display 3 is supported at a rear end 2a of the main body 2 by a pair of hinges 30a and 30b. As shown in FIGS. 9, 10, and 11, the hinges 30a and 30b are apart from each other in the width direction of the display 3. The hinges 30a and 30b each comprise a hinge shaft 31, a first metal bracket 32, and a second metal bracket 33.

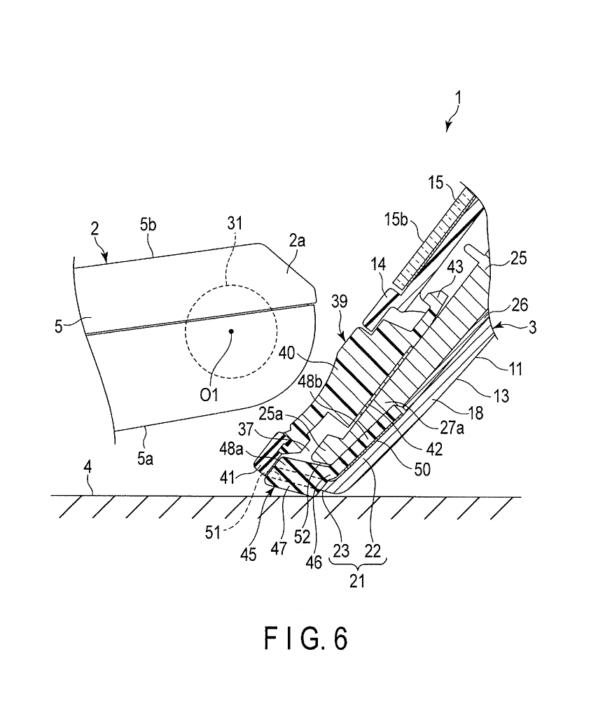

The hinge shaft 31 has a center axis O1 extending horizontally in the width direction of the display 3. To the hinge shaft 31, the first metal bracket 32 is connected to be pivotable about an axial direction of the hinge shaft 31. The first metal bracket 32 protrudes from the hinge shaft 31 in a direction perpendicular to the hinge shaft 31, and is fixed to the first housing 5. As shown in FIG. 6, the hinge shaft 31 and the first metal bracket 32 are contained in the first housing 5 to be positioned at the rear end 2a of the main body 2. The hinge shaft 31 is positioned lower than the upper surface 5b of the first housing 5.

Further, a braking force is applied to the first metal bracket 32 through a brake mechanism 34 configured by combining, for example, a plurality of washer springs and stoppers. In this manner, free pivoting of the first metal bracket 32 is restricted in relation to the hinge shaft 31.

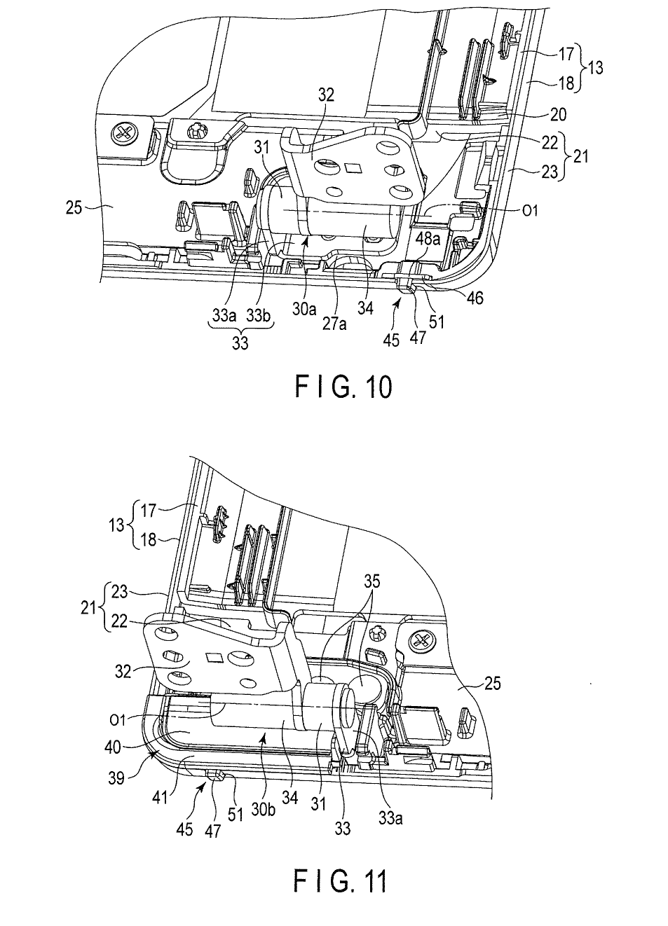

As shown in FIGS. 10 and 11, the second metal bracket 33 is fixed to an end of the hinge shaft 31. The second metal bracket 33 comprises an arm part 33a and a fixing seat part 33b. The arm part 33a protrudes from the end of the hinge shaft 31 in a direction perpendicular to the hinge shaft 31. The fixing seat part 33b is formed to continue to a protruding end of the arm part 33a. The fixing seat part 33b is formed in a flat plate shape parallel to the hinge shaft 31.

According to the first embodiment, the fixing seat part 33b of the second metal bracket 33 is fixed by a plurality of pins 35 to the hinge fixing parts 27a and 27b of the middle frame 25. The pins 35 bridge between the hinge fixing parts 27a and 27b and the fixing seat part 33b, and have tip ends caulked. In this manner, the second metal bracket 33 of each of the hinges 30a and 30b is integrally held by the second housing 11.

The arm part 33a of each of the second metal brackets 33 penetrates the end 37 of the display 3, and is guided to the rear end 2a of the main body 2. Therefore, the display 3 can be pivoted among a closed position, an intermediate position, and an exploded position about the hinge shafts 31 as a fulcrum.

FIG. 4 shows a state in which the display 3 is pivoted to the closed position. At the closed position, the display 3 lies over the main body 2, covering the palm rest 7 and the keyboard 8.

A two-dot chain line in FIG. 2 and FIG. 6 show a state in which the display 3 is pivoted to the intermediate position. At the intermediate position, the display 3 stands up from the rear end 2a of the main body 2, exposing the palm rest 7 and the keyboard 8.

Further, a solid line in FIG. 2 and FIG. 6 show a state in which the display 3 is pivoted to the exploded position. At the exploded position, the display 3 lies down behind the main body 2.

As enlarged and shown in FIG. 3, in the state in which the display 3 is pivoted to the exploded position, the end 37 of the display 3 enters between the installation surface 4 and the rear end 2a of the main body 2. Therefore, where the display 3 is laid down to the maximum, the main body 2 and the display 3 are shaped to be approximately horizontally continuous to each other on the installation surface 4. Conveniences are accordingly obtained when the display 3 is used as a tablet.

As shown in FIG. 5, the fixing seat part 33b of the second metal bracket 33 of each of the hinges 30a and 30b is partially covered with the display mask 14. Further, a part of the fixing seat part 33b which is out of the display mask 14 is covered with the hinge cover 39a for each of the hinges 30a and 30b. The hinge cover 39 is continuous to the display mask 14 and is at the end 37 of the display 3.

The hinge cover 39 comprises a plate part 40 made of hard resin, and an edge part 41 formed integrally with an outer peripheral part of the plate part 40. The edge part 41 is made of a rubber elastic material which is softer than the plate part 40.

As shown in FIGS. 6 and 8, the plate part 40 of the hinge cover 39 is temporarily secured to the hinge fixing parts 27a and 27b of the middle frame 25 by double-sided adhesive tape 42. The peripheral edge part of the plate part 40 is sandwiched between the display mask 14 and the hinge fixing parts 27a and 27b of the middle frame 25. A plurality of claws 43 (only one of which is illustrated in FIG. 6) engage with the display mask 14 and the middle frame 25 which are formed on the plate part 40.

As shown in FIGS. 3 and 5, the edge part 41 of the hinge cover 39 is brought into contact with a tip edge of the peripheral wall part 23, so as to be continuous to the peripheral wall part 23 of the second cover part 18 at the end 37 of the display 3.

As shown in FIGS. 9, 10, and 11, a pair of protectors 45 are attached to the display cover 13. When the display 3 is pivoted to the exploded position from the intermediate position, the protectors 45 are elements for preventing the end 37 of the display 3 and the installation surface 4 from rubbing each other and being damaged.

The protectors 45 are apart from each other in the width direction of the display 3. When the display 3 is pivoted to the intermediate position or the exploded position, the protectors 45 are positioned at the lower end of the display 3 and face the installation surface 4. According to the first embodiment, the protectors 45 each are configured by, for example, a rubber elastic material such as an elastomer.

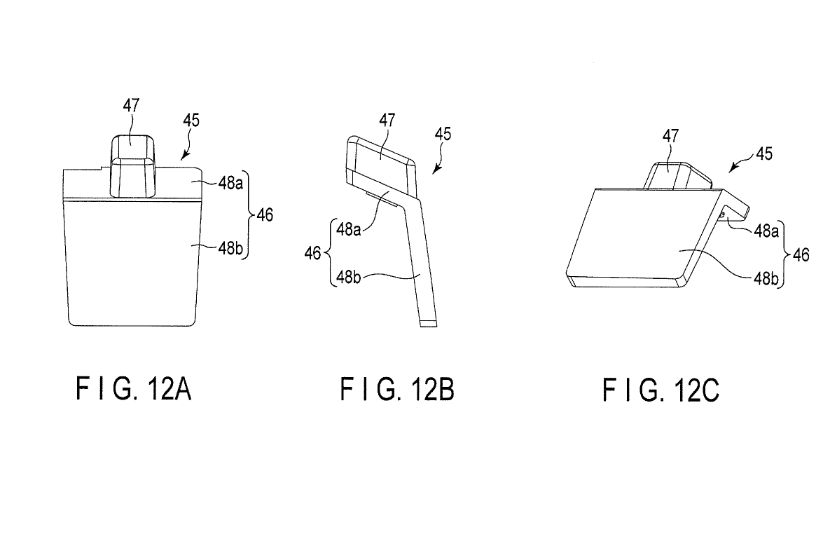

As shown in FIGS. 12A, 12B, and 12C, each of the protectors 45 comprises a base part 46 and a protrusion 47. The base part 46 is an element contained in the second cover part 18 of the display cover 13. The base part 46 comprises a first part 48a and a second part 48b.

The first part 48a has a rectangular shape which fits the peripheral wall part 23 of the second cover part 18 which forms the display cover 13. The first part 48a is in contact with the inner surface of the peripheral wall part 23. The second part 48b is integrally extended from an end of the first part 48a along the main wall part 22 of the second cover part 18, and extends in the direction which intersects the first part 48a. Therefore, the base part 46 is acutely bent at the boundary between the first part 48a and the second part 48b. Further, the second part 48b has a greater rectangular shape than the first part 48a.

As most appropriately shown in FIG. 6, the second part 48b of the base part 46 is temporarily secured to the inner surface of the main wall part 22 by double-sided adhesive tape 50. In addition, the second part 48b intervenes between the main wall part 22 and the middle frame 25, and is sandwiched between the main wall part 22 and the middle frame 25 in the thickness direction of the second housing 11.

The protrusion 47 of each of the protectors 45 protrudes integrally from the center of the first part 48a of the base part 46. The protrusion 47 has an elongate plate shape which extends in a direction perpendicular to the center axis O1 of the hinge shafts 31. According to the first embodiment, the base part 46 including the first part 48a and the second part 48b has a greater shape than the protrusion 47.

The protrusions 47 protrude outside of the end 37 of the display 3 through slits 51 provided in the peripheral wall part 23 of the second cover part 18. The slits 51 extend along the thickness direction of the second housing 11 and are opened in the tip edge of the peripheral wall part 23. The open end of each of the slits 51 is closed at the edge part 41 of the hinge cover 39.

As shown in FIG. 6, the first part 48a of the base part 46 faces the end 25a of the middle frame 25 between the main wall part 22 of the second cover part 18 and the hinge cover 39. In other words, the first parts 48a of the base parts 46 intervenes between the main wall part 23 of the second cover part 18 and the end 25a of the middle frame 25.

According to the first embodiment, the end 25a of the middle frame 25 faces the first parts 48a from the side opposite to the protrusions 47. A gap 52 is maintained between the first part 48a and the end 25a of the middle frame 25.

Further, the first parts 48a are brought into contact with the inner surface of the peripheral wall part 23, thereby covering the slits 51 from inside of the second cover part 18. Therefore, foreign materials such as dust do not enter into inside of the second housing 11 through the slits 51.

The protrusions 47 of the protectors 45 extend linearly along the depth direction of the portable computer 1, when the display 3 is pivoted to the exploded position. As shown in FIG. 3, when the display 3 is pivoted from the intermediate position to the exploded position, the end 37 of the display 3 moves down along an arcuate route centering on the hinge shafts 31 behind the back of the main body 2.

When the end 37 of the display 3 is moved to just enter between the rear end 2a of the main body 2 and the installation surface 4, the protrusions 47 of the protectors 45 are brought into contact with the installation surface 4. In this manner, the rear end 2a of the main body 2 is lifted up from the installation surface 4, and the pair of feet 6 positioned at the rear end 2a of the main body 2 move apart from the installation surface 4.

Even when the rear end 2a of the main body 2 is lifted up from the installation surface 4, the pair of feet 6 positioned in the front end of the main body 2 are in contact with the installation surface 4, and the protrusions 47 of the protectors 45 fixed to the display 3 are in contact with the installation surface 4 under the rear end 2a of the main body 2. Accordingly, the main body 2 is supported on the installation surface 4 at four positions, as in case where the display 3 is pivoted to the closed position. As a result, the posture of the portable computer 1 placed on the installation surface 4 is stabilized.

Further, the feet 6 and the protrusions 47 are both made of a rubber-based elastic material having a large coefficient of friction. Therefore, the portable computer 1 set on the installation surface 4 can be prevented from sliding.

According to the first embodiment, the base parts 46 of the protectors 45 each have a greater shape than the protrusions 47 protruding outside of the display 3. The first parts 48a of the base parts 46 each are provided along the inner surface of the peripheral wall part 23 of the second cover part 18. The second parts 48b each are provided along the inner surface of the main wall part 22 of the second cover part 18. As a result, for example, even when a force in the direction of pulling the protrusions 47 out of the slits 51 is applied to the protectors 45, the base parts 46 of the protectors 45 engages with the peripheral wall part 23 of the second cover part 18 or the main wall part 22.

In addition, the second parts 48b of the base parts 46 are sandwiched between the main wall part 22 and the middle frame 25 bonded to the inner surface of the main wall part 22 in the thickness direction of the second housing 11. Therefore, the second parts 48b each are pressed down from a direction in which the protrusions 47 are pressed by the installation surface 4 and also from a direction which intersects a direction of pulling out the protrusions 47 from the slits 51. Accordingly, the protectors 45 hardly move in relation to the second housing 11.

In addition, open ends of the slits 51 which the protrusions 47 penetrate are closed by the edge part 41 of the hinge cover 39. Therefore, the protrusions 47 do not come out of the open ends of the slits 51.

Accordingly, the protectors 45 can be fixed to inside of the second housing 11 firmly. Therefore, even when the protrusions 47 of the protectors 45 rub the installation surface 4 in accordance with pivoting of the display 3, the protectors 45 can be prevented from peeling and falling off.

Further, the first parts 48a of the base parts 46 which include the protrusions 47 intervene between the end 25a of the middle frame 25 and the peripheral wall part 23 of the second cover part 18. Therefore, even if an impact is applied to push the protrusions 47 into the slits 51, the first parts 48a of the base parts 46 are brought into contact with the end 25a of the middle frame 25. As a result, the protrusions 47 can be prevented from retracting back into the second housing 11.

On the other side, in the first embodiment, the display cover 13 is configured by combining the first cover part 17 and the second cover part 18 with each other. The middle frame 25 is bonded to the main wall part 22 of the second cover part 18.

According to this configuration, dimensional tolerances which occur, for example, to a junction between the first cover part 17 and the second cover part 18 and to a junction between the second cover part 18 and the middle frame 25 act in a multiplicated manner between the peripheral wall part 23 of the second cover part 18 and the end 25a of the middle frame 25.

In this manner, dimensions slightly vary between the peripheral wall part 23 of the second cover part 18 and the end 25a of the middle frame 25. As a result, depending on values of the foregoing dimensional tolerances, the dimensions of the peripheral wall part 23 of the second cover part 18 and the end 25a of the middle frame 25 are smaller than predetermined values, and the protectors 45 can be prevented from being attached.

Hence in the first embodiment, the gap 52 is maintained between the first parts 48a of the base parts 46 and the end 25a of the middle frame 25. The gap 52 absorbs the dimensional tolerances which act between the peripheral wall part 23 of the second cover part 18 and the end 25a of the middle frame 25.

Accordingly, the base parts 46 of the protectors 45 can naturally be set between the display cover 13 and the middle frame 25.

### Second Embodiment

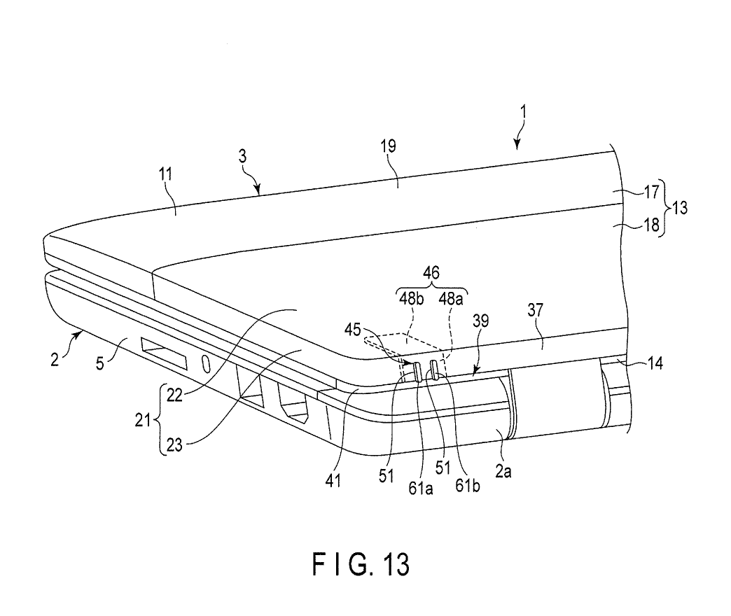

FIG. 13 discloses the second embodiment.

The second embodiment differs from the first embodiment in that the protectors 45 each comprise a pair of protrusions 61a and 61b. Other features of the configuration of the portable computer 1 are the same as those of the first embodiment.

The protrusions 61a and 61b protrude integrally from a first part 48a of each of base parts 46, and are arranged at an interval between in the width direction of a display 3.

According to the second embodiment, when the display 3 is pivoted to an exploded position on the installation surface 4, the protrusions 61a and 61b are brought into contact with the installation surface 4. Therefore, a load applied to each one of the protrusions 61a and 61b is reduced, and the protrusions 61a and 61b can be prevented from damages and deterioration.

### Third Embodiment

FIG. 14 discloses the third embodiment.

The third embodiment differs from the first embodiment in that each of protrusions 47 of protectors 45 includes an extension part 71 which hangs over the main wall part 22. Other features of the configuration of the portable computer 1 are the same as those of the first embodiment.

The extension part 71 protrudes integrally from a second part 48b of the base part 46 so as to penetrate the main wall part 22. That is, in the third embodiment, slits 51 of a second cover part 18 have open ends 51 which are open to continue to the main wall part 22 from the peripheral wall part 23. The extension parts 71 of protrusions 47a protrude outside of the main wall part 22 through the open ends 51a of the slits 51.

According to the third embodiment, when the display 3 is pivoted to the maximum along the installation surface 4, the extension parts 71 of the protrusions 47 are brought into contact with an installation surface 4. Therefore, the outer surface of the main wall part 22 is lifted up from the installation surface 4 only to an extent equivalent to the height of the extension parts 71. Accordingly, the outer surface of the main wall part 22 can be prevented from damages.

In the first embodiment, the base parts of the protectors are sandwiched between the middle frame which fixes hinges and the display cover. The first embodiment, however, is not limited to this configuration. For example, the base parts of the protectors may be sandwiched between another component contained in the housing and the display cover.

Further, for example, boss parts protruding toward the display cover may be formed on the display mask. The base parts of the protectors may be sandwiched between the boss parts and the display cover.

Also in the first embodiment, the display is an example of a pivotable member. The pivotable member may be a cover which covers a main body to be openable and closable.

In addition, the protectors need not always be made of a rubber-based elastic material but may be made of a synthetic resin material.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electronic apparatus comprising:
a main body placed on an installation surface;
a pivotable member supported pivotably at a rear end of the main body, and comprising an end which enters between the rear end of the main body and the installation surface when the pivotable member is pivoted to a position where the pivotable member lies down behind the main body; and
a protector provided at the end of the pivotable member and comprising a base part fixed to the pivotable member inside the end, and a protrusion protruding outside of the end from the base part, and the protrusion configured to be in contact with the installation surface, the base part having a greater shape than the protrusion.

2. The electronic apparatus of claim 1, further comprising a hinge which pivotably connects the pivotable member to a rear end of the main body, the hinge comprising a center axis extending in a width direction of the main body, and the protrusion of the protector having an elongate shape extended in a direction which intersects the center axis.

3. The electronic apparatus of claim 2, wherein when the pivotable member is pivoted to lie down behind the main body, the protrusion of the protector extends in a depth direction of the main body between the rear end of the main body and the installation surface.

4. The electronic apparatus of claim 1, wherein
the pivotable member comprises a housing comprising an outer wall,
a slit which the protrusion penetrates is provided in the outer wall of the housing, and
the slit comprises an open end opened in an edge of the outer wall, and the open end of the slit is closed by the cover.

5. The electronic apparatus of claim 4, wherein
the pivotable member comprises a holder member contained in the housing, and
the base part of the protector is sandwiched between the outer wall of the housing and the holder member.

6. The electronic apparatus of claim 1, wherein the protector is made of a rubber-based elastic material.

7. An electronic apparatus comprising:
a first housing placed on an installation surface;
a second housing supported at a rear end of the first housing, to be pivotable between a closed position of covering the first housing and an exploded position of lying down behind the first housing, the second housing comprising an end which enters between the rear end of the first housing and the installation surface when the second housing is pivoted to the exploded position;
a holder member which faces an outer wall of the second housing inside the second housing; and
a protector sandwiched between the outer wall of the second housing and the holder member and protruding from the end of the second housing, the protector being configured to be brought into contact with the installation surface when the second housing is pivoted to the exploded position.

8. The electronic apparatus of claim 7, wherein the protector comprises a base part where the protrusion protrudes, and the base part intervenes between the outer wall and the holder member.

9. The electronic apparatus of claim 8, wherein
the outer wall comprises a main wall part where the holder member is fixed, and a peripheral wall part which stands from an outer peripheral edge of the main wall part so as to surround the main wall part,
the base part of the protector comprises a first part along the peripheral wall part and a second part along the main wall part,
the protrusion protrudes from the first part, and
the second part is sandwiched between the main wall part and the holder member.

10. The electronic apparatus of claim 9, wherein the second part of the base part is sandwiched between the main wall part and the holder member in a direction intersecting a direction in which the protrusion is pressed by the installation surface.

11. The electronic apparatus of claim 9, wherein the holder member comprises an end facing the first part from an opposite side to the protrusion, and a gap is provided between the end and the first part.

12. The electronic apparatus of claim 11, wherein the holder member is fixed to the main wall part by an adhesive agent.

13. The electronic apparatus of claim 9, wherein
a through hole which the protrusion penetrates is provided in the peripheral wall part of the housing, and
the through hole has an open end opened in an edge of the peripheral wall part and closed with a cover.

14. The electronic apparatus of claim 13, further comprising a hinge which pivotably connects the second housing to the first housing, wherein
the hinge comprises a hinge shaft arranged inside the first housing and a bracket protruding towards the end of the second housing from the hinge shaft, and the bracket is fixed to the holder member.

15. The electronic apparatus of claim 7, wherein the protector is made of a rubber-based elastic material.

16. An electronic apparatus comprising:
a first housing set on an installation surface;
a second housing which is supported at a rear end of the first housing and is pivotable so as to lie down behind the first housing;
a holder member positioned inside the second housing; and
a protector comprising a base part sandwiched between the second housing and the holder member, and a protrusion protruding outside of the second housing from the base part, the protrusion being configured to be brought into contact with the installation surface when the second housing is pivoted so as to lie down behind the first housing, and the base part having a greater shape than the protrusion.

17. The electronic apparatus of claim 16, wherein the protector is made of a rubber-based elastic material.
